(19) United States
(12) Patent Application Publication
(10) Pub. No.: US 2010/0111770 A1
(43) Pub. Date: May 6, 2010

(54) Microfluidic Chip and Method of Fabricating The Same

(75) Inventors: Kyu-youn HWANG, Yongin-si (KR); Joon-ho KIM, Seongnam-si (KR); Chin-sung PARK, Yongin-si (KR); Sung-young JEONG, Yongin-si (KR); Taeseok SIM, Seoul (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/613,847

(22) Filed: Nov. 6, 2009

Related U.S. Application Data
(63) Continuation-in-part of application No. 11/934,811, filed on Nov. 5, 2007.

(30) Foreign Application Priority Data
Jun. 7, 2007 (KR) 10-2007-0055716
Nov. 6, 2008 (KR) 10-2008-110004

(51) Int. Cl. B81B 3/00; B32B 37/14; B32B 3/02; B32B 9/00

(52) U.S. Cl. 422/100; 156/151; 428/447; 428/429; 428/422; 428/412; 428/425.5; 428/172

(57) ABSTRACT

Provided are a microfluidic structure including a polysiloxane layer and a method of fabricating the microfluidic structure. The polysiloxane layer is coupled to substrates via a SiO₂ layer.

### CROSS-REFERENCE TO RELATED PATENT APPLICATIONS

This application is a continuation-in-part application of U.S. patent application Ser. No. 11/934,811 filed on Nov. 5, 2007, which claims the benefit of Korean Patent Application No. 10-2007-0055716, filed on Jun. 7, 2007; this application claims the benefit of Korean Application No. 10-2008-110004, filed on Nov. 6, 2008, in the Korean Intellectual Property Office, the disclosures of which are incorporated herein in their entirety by reference.

### BACKGROUND

1. Field of the Invention

One or more embodiments relate to microfluidics, and more particularly, to a microfluidic chip and a method of fabricating the microfluidic chip.

2. Description of the Related Art

Microfluidic chips, that is, chip-shaped devices, are used in microfluidics to perform various biochemical reactions using a small amount of biochemical fluid or to process a biochemical fluid for biochemical reactions. In general, a microfluidic chip includes an inlet hole for injecting a biochemical fluid into the microfluidic chip, an outlet hole for discharging the biochemical fluid out of the microfluidic chip, a channel through which the biochemical fluid can flow, and a chamber in which the biochemical fluid is received.

Microfluidic chips could have the organic thin films on an inner surface of the chamber using an organosilane-based material in order to capture the cells present in a biochemical fluid or to purify DNA extracted from the cells, which are well known. Such a conventional microfluidic chip includes a lower substrate formed of silicon (Si) and an upper substrate formed of a transparent glass material, and the lower substrate and the upper substrate are attached to each other using an anodic bonding method. The anodic bonding may destroy an organosilane-based material since it requires a high temperature condition of 400° C. or higher. Therefore, after attaching the lower substrate and the upper substrate using the anodic bonding method, the organic thin film is formed through the holes on inner surfaces of the chamber and the channel using a chemical vapor deposition (CVD) method.

Microfluidic devices are used in various fields. For example, the microfluidic device may be used as an analyzing apparatus of a high throughput. The microfluidic device includes microfluidic structures such as channels and chambers. The microfluidic device may be fabricated in various ways. Microfluidic fabricating technologies such as lithography, etching, depositing, micromachining, and Lithographie, Galvanoformung, and Abformung (LIGA) processes may be used to fabricate the microfluidic devices.

The microfluidic device may be fabricated by forming microfluidic structures on two substrates and coupling the substrates to each other. For example, the microfluidic structures may be formed on two glass substrates, and the glass substrates are coupled to each other to fabricate the microfluidic device. Each of the two substrates includes entire or a part of the microfluidic structures.

The conventional microfluidic chip uses the expensive inorganic materials such as silicon or glass, and the lower substrate and the upper substrate are attached to each other using the anodic bonding method that requires the high temperature condition. In addition, since the organic thin film should be formed through the holes after attaching the lower substrate and the upper substrate to each other, the fabrication costs of the conventional microfluidic chip increase and the uniformity of generated organic thin film is not guaranteed. In addition, a method for effectively forming the microfluidic structures on the substrate and coupling the substrates on which the microfluidic structures are formed, and a microfluidic device fabricated by the above method are required.

### SUMMARY

One or more embodiments provide a microfluidic chip including a lower substrate and an upper substrate attached to each other using a novel bonding method instead of an anodic bonding, and including an organic thin film formed on an inner surface of a chamber, and a method of fabricating the microfluidic chip.

According to an aspect, there is provided a microfluidic chip including: a lower substrate including a channel, through which a biochemical fluid can flow, and a chamber, in which the biochemical fluid can be received, formed on an upper surface of the lower substrate; an upper substrate formed of a silicon resin, and having a lower surface attached to the upper surface of the lower substrate; and an organic thin film formed on the upper surface of the lower substrate except for portions on which the lower substrate and the upper substrate are attached to each other, wherein the lower surface of the upper substrate is activated by an O₂-plasma process, and the lower surface of the upper substrate is adhered to the upper surface of the lower substrate so that the lower substrate and the upper substrate can be attached to each other.

The microfluidic chip may further include: a unit for enlarging a contact surface area with the biochemical fluid in the chamber.

The unit for enlarging the contact surface area may include a plurality of pillars protruding from the lower substrate so that they contact the lower surface of the upper substrate, and they are separately arranged from one another.

The organic thin film may be formed on a surface of the unit for enlarging the contact surface area.

The silicon resin of the upper substrate may be PDMS (polydimethylsiloxane).

The lower substrate may include Si, SiO₂, SiN, or a polymer.

The organic thin film may be a SAM (self-assembled monolayer).

The organic thin film may include an organosilane-based material.

The organosilane-based material may have an alkoxysilane group or a chlorosilane group.

A photocatalyst layer including a photocatalyst material may be disposed between the lower substrate and the organic thin film.

The photocatalyst material may be TiO₂, ZnO, SnO₂, SrTiO₃, WO₃, B₂O₃, or Fe₂O₃.

The lower substrate may include a photocatalyst material.

The photocatalyst material may be TiO₂.

An oxide layer or a nitride layer may be formed on portions of the upper surface of the lower substrate, which contact the lower surface of the upper substrate.

The oxide layer may include SiO₂ or TiO₂.

The nitride layer may include SiN.

According to another aspect, there is provided a method of fabricating a microfluidic chip, the method including: forming a lower substrate including a channel, through which a biochemical fluid can flow, and a chamber, in which the biochemical fluid can be received, on an upper surface of the lower substrate; forming an upper substrate including a silicon resin; forming an organic thin film on the upper surface of the lower substrate; removing the organic thin film that is formed on portions of the lower substrate, which will be attached to the upper substrate; and activating a lower surface of the upper substrate using an O₂-plasma process, and adhering the upper substrate to the lower substrate to attach the upper and lower substrates to each other.

The formation of the organic thin film may include: coating the lower substrate with a solution including the material forming the organic thin film.

The removal of the organic thin film may include: forming a photo mask including a flat transparent plate, a photoresist layer including a pattern corresponding to the portions, from which the organic thin film will be removed, on the transparent plate, and a photocatalyst layer including a photocatalyst material formed on a lower surface of the transparent plate; arranging the photo mask on the upper surface of the lower substrate so that the photocatalyst layer can contact the organic thin film; and irradiating ultraviolet (UV) rays to the photo mask so that the organic thin film that contacts the photocatalyst layer and is exposed to the UV rays can be decomposed.

The removal of the organic thin film may include: placing a flat photocatalyst plate including a photocatalyst material on the lower substrate on which the organic thin film is formed; and irradiating the UV rays to the photocatalyst plate to decompose the organic thin film that contacts the photocatalyst plate and is exposed to the UV rays.

The method may further include: forming a photocatalyst layer including a photocatalyst material on the upper surface of the lower substrate before forming of the organic thin film, and forming the organic thin film on the photocatalyst layer in the process of forming the organic thin film, wherein the removal of the organic thin film includes: forming a photo mask including a flat transparent plate and a photoresist layer including a pattern corresponding to portions, from which the organic thin film will be removed, on the transparent plate; arranging the photo mask on the upper surface of the lower substrate; and irradiating the UV rays to the photo mask so that the organic thin film that contacts the photocatalyst layer and is exposed to the UV rays can be decomposed.

One or more embodiments may include a microfluidic structure including a polysiloxane layer.

One or more embodiments may include a method of fabricating a microfluidic structure by using a polysiloxane layer.

According to one or more embodiments, the microfluidic structure includes: a first substrate; a second substrate; and a polysiloxane layer disposed between the first and second substrates, wherein the polysiloxane layer is coupled to the first and second substrates via an SiO₂ layer.

According to one or more embodiments, the method of fabricating a microfluidic structure includes: providing a first substrate and a second substrate on which micro-structures are formed; depositing an SiO₂ layer on surfaces of the first and second substrates; and coupling the first and second substrates to each other by interposing a polysiloxane layer between the surfaces, on which the SiO₂ layer is deposited, of the first and second substrates.

### BRIEF DESCRIPTION OF THE DRAWINGS

The above and other features and advantages will become more apparent by describing in detail exemplary embodiments thereof with reference to the attached drawings in which:

FIG. 1 is a partially cut exploded perspective view of a microfluidic chip according to an embodiment;

FIGS. 2A through 2G are cross-sectional views illustrating a method of fabricating the microfluidic chip of FIG. 1;

FIGS. 3A through 3E are cross-sectional views illustrating a method of fabricating a microfluidic chip according to another embodiment;

FIG. 4 is a partially cut perspective view of a microfluidic chip according to another embodiment;

FIGS. 5A through 5G are cross-sectional views sequentially illustrating a method of fabricating the microfluidic chip of FIG. 4, according to another embodiment; and

FIG. 6 is a partially cut perspective view of a microfluidic chip according to another embodiment;

FIGS. 7A and 7B are diagrams of a microfluidic structure according to another embodiment;

FIG. 8 is a diagram illustrating a method of fabricating a microfluidic structure according to another embodiment;

FIGS. 9A through 9C are diagrams of a microfluidic structure according to another embodiment; and

FIGS. 10A and 10B are diagrams of a pump which is fabricated by using film valves.

### DETAILED DESCRIPTION

Hereinafter, a microfluidic chip and a method of fabricating the same will be described with reference to accompanying drawings.

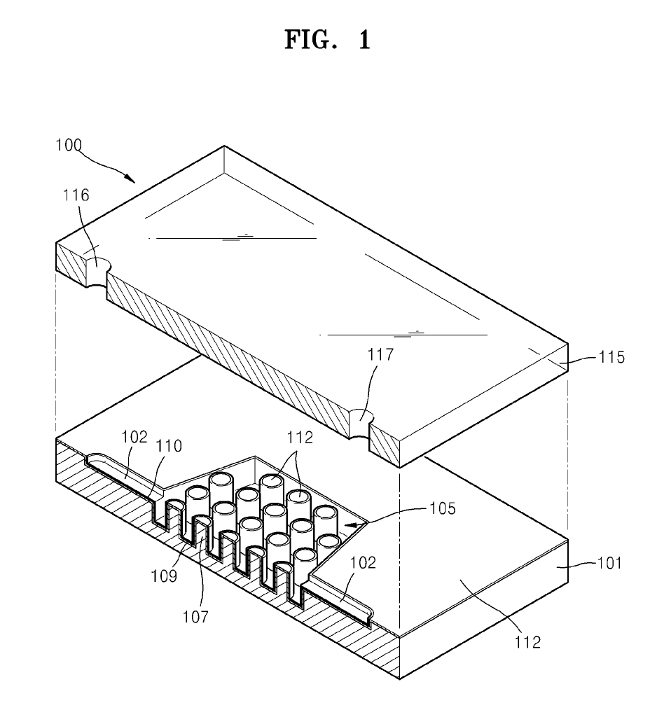

FIG. 1 is a partially cut exploded perspective view of a microfluidic chip 100 according to an embodiment.

Referring to FIG. 1, the microfluidic chip 100 of the current embodiment includes a lower substrate 101 and an upper substrate 115, which are attached to each other. The lower substrate 101 is formed of a Si material, and includes a channel 102, through which a fluid can flow, and a chamber 105 receiving the fluid in a center portion of the channel 102 on an upper surface thereof. A plurality of pillars 107 are formed in the chamber 105. The pillar 107 is a unit for enlarging an surface area contacting the fluid induced in the chamber 105. The pillars 107 are separated from each other in the chamber 105, and protrude out of the upper surface of the lower substrate 101 so that they contact a lower surface of the upper substrate 115.

The surface of the lower substrate 101 formed of the Si material is oxidized by oxygen in the air, and thus, an oxide layer 109 including SiO₂ is formed. The oxide layer 109 has a function of attaching the upper substrate 115 and the lower substrate 101 to each other. On the other hand, the lower substrate 101 may be formed of a polymer resin such as PDMS (polydimethylsiloxane), PMMA (polymethylmetaacrylate), PC (polycarbonate), and PE (polyethylene). If the lower substrate 101 is formed of the polymer resin, the oxide layer 109 is not formed. Therefore, an oxide layer including SiO₂ or TiO₂ or a nitride layer including SiN should be specifically formed. In order to form the oxide layer or the nitride layer, a CVD method or a physical vapor deposition (PVD) method can be used. In addition, the lower substrate 101 may be formed of SiO₂ or SiN. In this case, since the lower substrate 101 is formed of the oxide material or the nitride material, an additional oxide layer or a nitride layer is not required.

An organic thin film 110 is formed on the upper surface of the lower substrate 101. The organic thin film 110 is coated to capture in the chamber 105 certain cells such as bacteria included in a biochemical fluid injected into the microfluidic chip 100 or to purify DNA extracted from the cells in the chamber 105. The organic thin film may include an organosilane based material, and can be stacked as a self-assembled monolayer. The organic thin film 110 is also formed on surfaces of the plurality of pillars 107. The organosilane-based material can be an alkoxysilane group material or a chlorosilane group material. The alkoxysilane group material can be octadecyldimethyl(3-trimethoxysilyl propyl) ammonium chloride, polyethyleneiminertrimethoxysilane, and aminopropyltriethoxysilane, and the chlorosilane group material can be octadecyltrichlorosilane.

The organic thin film 110 is mostly formed of a hydrophobic material, and thus, interferes with the attachment between the lower substrate 101 and the upper substrate 115. Therefore, the organic thin film formed on areas 112 on the upper surface of the lower substrate 101, which are attached to the upper substrate 115, is removed. Hereinafter, the area 112 will be referred to as an attaching area.

The upper substrate 115 is formed of a silicon resin, for example, PDMS (polydimethylsiloxane). The upper substrate 115 includes an inlet hole 116 connected to a side of the channel 102 of the chamber 105 so as to inject the biochemical fluid into the microfluidic chip 100, and an outlet hole 117 connected to the other side of the channel 102 of the chamber 105 so as to exhaust the biochemical fluid out of the microfluidic chip 100. The method of attaching the lower substrate 101 and the upper substrate 115 will be described later.

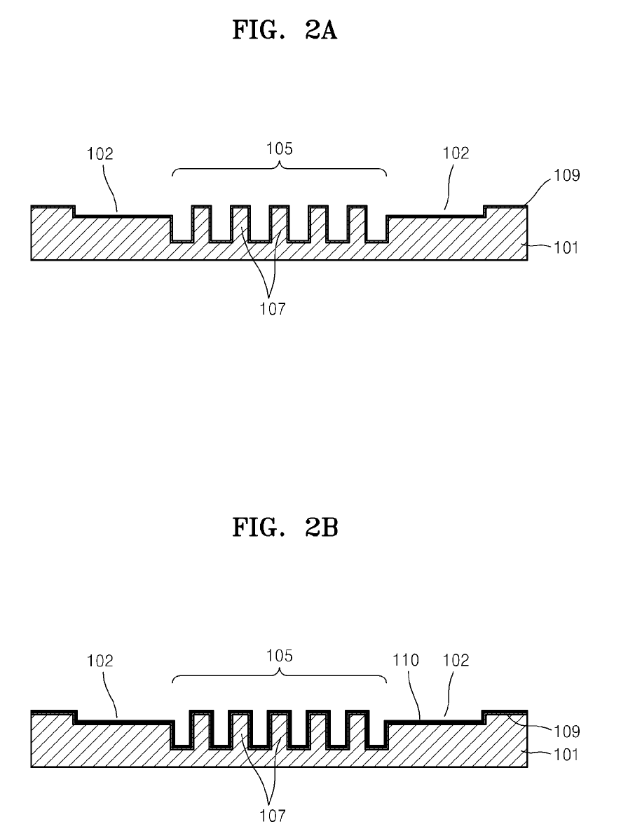

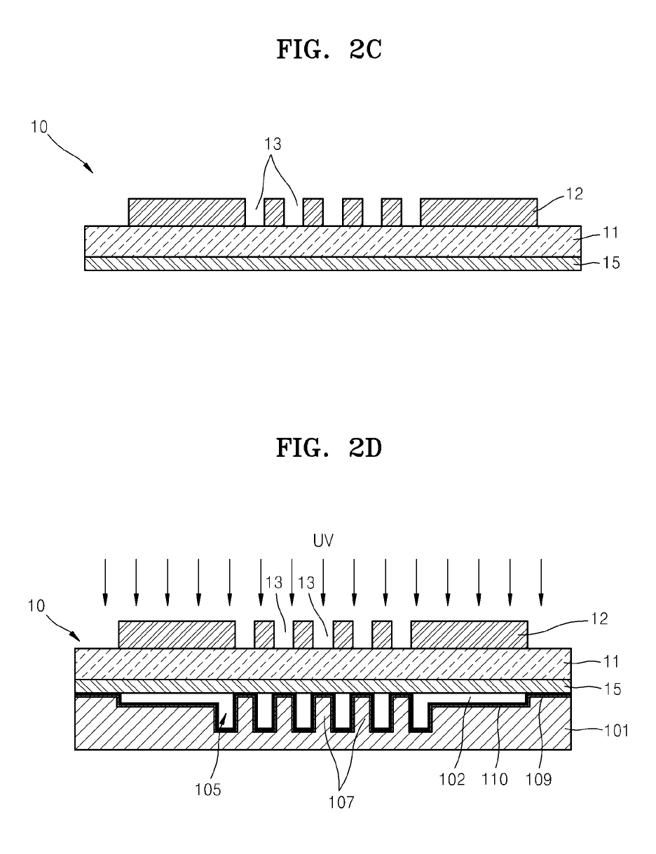

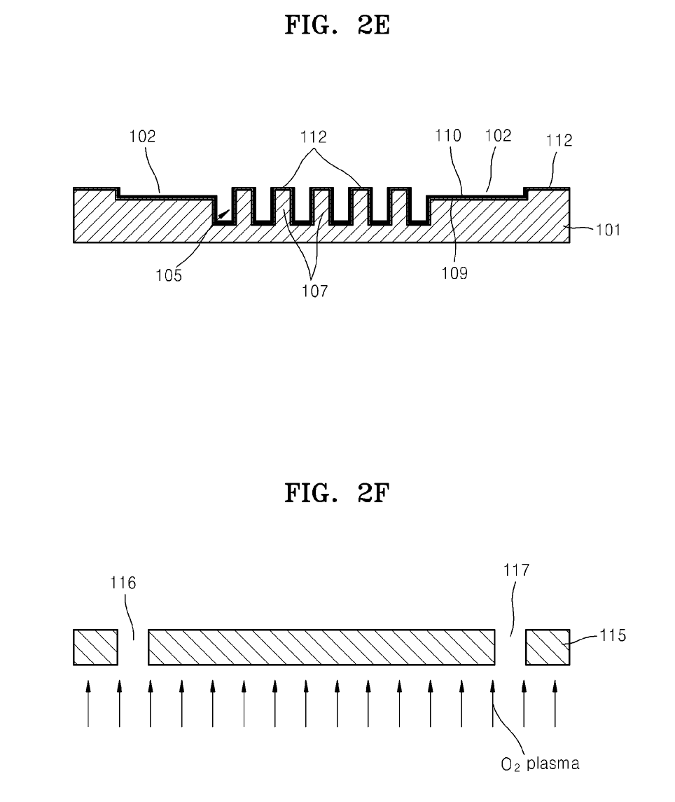

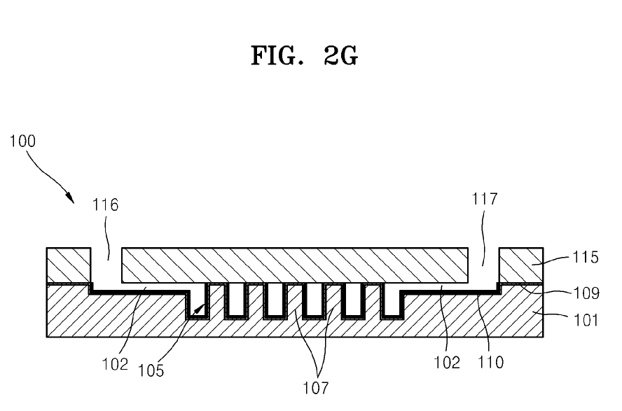

FIGS. 2A through 2G are cross-sectional views sequentially illustrating a method of fabricating the microfluidic chip of FIG. 1. Hereinafter, the method of fabricating the microfluidic chip 100 will be described in detail with reference to FIGS. 2A through 2G.

The method of fabricating the microfluidic chip 100 may include into a first process (refer to FIG. 2A) of forming the lower substrate 101 on which the channel 102 and the chamber 105 are formed, a second process (refer to FIG. 2F) of preparing the upper substrate 115 formed of Si, a third process (refer to FIG. 2B) of forming the organic thin film 110 on the upper surface of the lower substrate 101, a fourth process (refer to FIGS. 2C through 2E) of removing the organic thin film 110 formed on the attaching area 112 of the lower substrate 101, and a fifth process (refer to FIGS. 2F and 2G) of attaching the upper substrate 115 and the lower substrate 101 to each other.

Referring to FIG. 2A, the lower substrate 101 formed of the Si material is prepared, and the channel 102, the chamber 105, and the plurality of pillars 107 are formed on the upper surface of the lower substrate 101. An etch prevention layer (not shown) having patterns corresponding to the channel 102, the chamber 105, and the pillars 107 is formed on the upper surface of the lower substrate 101 using a photolithography method, and the upper surface of the lower substrate 101 is selectively removed using a wet etching process or a dry etching process to form the channel 102, the chamber 105, and the pillars 107. On the other hand, the channel 102, the chamber 105, and the pillars 107 can be formed using a general machining process such as a press process or a milling process.

The surface of the lower substrate 101, on which the channel 102, the chamber 105, and the pillars 107 are formed, is oxidized by the oxygen in the air, and the oxide layer 109 including SiO₂ is formed. The oxide layer 109 helps the attachment between the upper substrate 115 and the lower substrate 101. Meanwhile, the lower substrate 101 can be formed of a polymer resin such as PDMS (polydimethylsiloxane), PMMA (polymethylmetaacrylate), PC (polycarbonate), and PE (polyethylene). If the lower substrate 101 is formed of the polymer resin, the oxide layer 109 is not formed, and thus, the oxide layer including SiO₂ or TiO₂ or the nitride layer including SiN should be specifically formed. The oxide layer or the nitride layer can be formed using the CVD method or the PVD method.

In the second process, a mixed solution including the PDMS resin and a linking agent is injected into a mold (not shown) corresponding to the shape of the upper substrate 115 and is cured, and then, the cured shape is separated from the mold to form the upper substrate 115 (refer to FIG. 2F) formed of the PDMS. In more detail, Sylgard® 184 of Dow Corning Inc. is injected into the mold, and disposed under an optimal curing condition to form the upper substrate 115. For example, the optimal curing condition of Sylgard® 184 is to keep the product for 45 minutes at a temperature of 100° C., 20 minutes at a temperature of 125° C., or 10 minutes at a temperature of 150° C. Sylgard® 184 is an example of the mixed solution of the PDMS resin and the linking agent.

The inlet hole 116 and the outlet hole 117 can be formed using a general machining process such as a pressing process or a drilling process. Otherwise, a structure corresponding to the inlet hole 116 and the outlet hole 117 is disposed in the mold, and the mixed solution of the PDMS resin and the linking agent is injected into the mold to form the inlet hole 116 and the outlet hole 117.

Referring to FIG. 2B, the third process includes a coating process of dipping the upper surface of the lower substrate 101 into a solution including a material forming the organic thin film 110. In more detail, the upper surface of the lower substrate 101 is dipped into a solution including ethanol and octadecyldimethyl(3-trimethoxysilyl propyl) ammonium chloride that is the organosilane-based material for one hour, and after that, the lower substrate 101 is washed and disposed for 50 minutes at a temperature of 100° C. to form the organic thin film 110 on the upper surface of the lower substrate 101. The octadecyldimethyl(3-trimethoxysilyl propyl) ammonium chloride is an example of material forming the organic thin film 110, and can be substituted by other materials such as polyethyleneiminertrimethoxysilane, aminopropyltriethoxysilane, or octadecyltrichlorosilane.

The fourth process includes forming of a photomask 10 (refer to FIG. 2C), arranging the photomask 10 on the upper surface of the lower substrate 101 and irradiating ultraviolet rays onto the photomask 10 (refer to FIG. 2D), and removing the organic thin film 110 on the attaching area 112 on substrate 101 (refer to FIG. 2E).

Referring to FIG. 2C, the photomask 10 includes a flat transparent plate 11 formed of a transparent material such as glass, a photoresist layer 12 formed on the transparent plate 11, and a photocatalyst layer 15 formed on a lower surface of the transparent plate 11. The photoresist layer 12 includes a pattern 13 corresponding to the area, from which the organic thin film 110 will be removed, of the lower substrate 101, that is, the attaching area (112, refer to FIG. 1). The photoresist layer 12 including the pattern 13 by spin coating a liquid type photoresist on the transparent plate 11 and performing an exposure, a development, and a baking process to remove a certain area, or by laminating a film type photoresist on the transparent plate 11, and performing the exposure and the development process to remove a certain area.

The photocatalyst layer 15 is formed of a photocatalyst material. The photocatalyst material is a material causing a reaction of decomposing the organic thin film 110 when it is exposed to ultraviolet rays when contacting the organic thin film 110. For example, the photocatalyst material can be TiO₂, ZnO, SnO₂, SrTiO₃, WO3, B₂O₃, or Fe₂O₃. The photocatalyst layer 15 can be formed by spin coating TiO₂-sol solution on the lower surface of the transparent plate 11, and baking the coated layer. The TiO₂-sol solution can be formed by mixing titanium isopropoxide, isopropanol, and HCl of 0.1N, and stabilizing the mixed solution. Otherwise, the photocatalyst layer 15 can be formed using the CVD method or the PVD method.

Referring to FIG. 2D, the photomask 10 is arranged on the upper surface of the lower substrate 101 so that the pattern 13 of the photoresist layer 12 can overlap with the attaching area 112 (refer to FIG. 1), and ultraviolet rays (UV) are irradiated thereon. The regions of the lower substrate 101 contacting the photocatalyst layer 15 coincide with the attaching area 112. When the UV rays are irradiated onto the photomask 10, the photocatalyst layer 15 and the organic thin film 110 are partially exposed to the UV rays through the pattern 13. Therefore, some part of the organic thin film 110, which contacts the photocatalyst layer 15 and is exposed to the UV rays, is decomposed by the photocatalyst material.

Referring to FIG. 2E, when the photomask 10 is separated from the lower substrate 101 after irradiating the UV rays, the attaching area 112, from which the organic thin film 110 is removed by the decomposition operation of the photocatalyst material, is exposed.

Referring to FIG. 2F, the fifth process includes activating the lower surface of the upper substrate 115 so as to be easily attached to the lower substrate 101 by performing an O₂-plasma process on the lower surface of the upper substrate 115. In the O₂-plasma process, O₂-plasma particles are collided on the lower surface of the upper substrate 115. Next, as shown in FIG. 2G, the lower surface of the upper substrate 115 is adhered to the upper surface of the lower substrate 101 to be attached, and thus, the microfluidic chip 100 is formed. When the oxide layer 109 exposed on the attaching area 112 (refer to FIG. 2E) of the lower substrate 101 is adhered to the lower surface of the upper substrate 115 that is O₂-plasma processed, the contact surfaces of the substrates 101 and 115 are attached to each other by a dehydration-condensation.

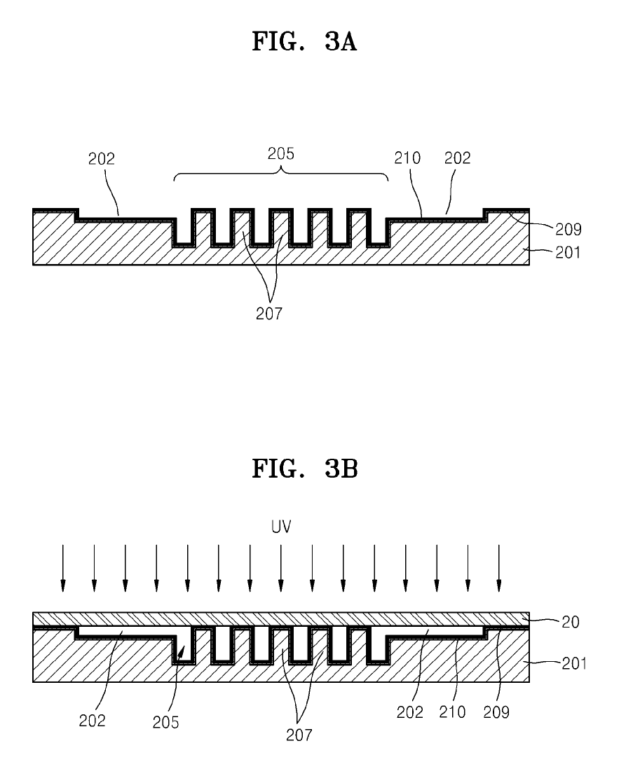

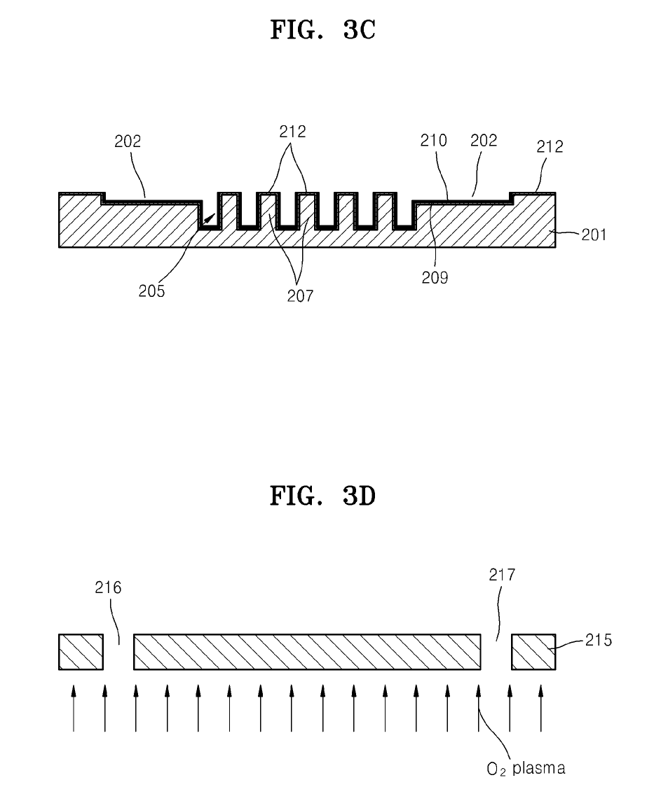

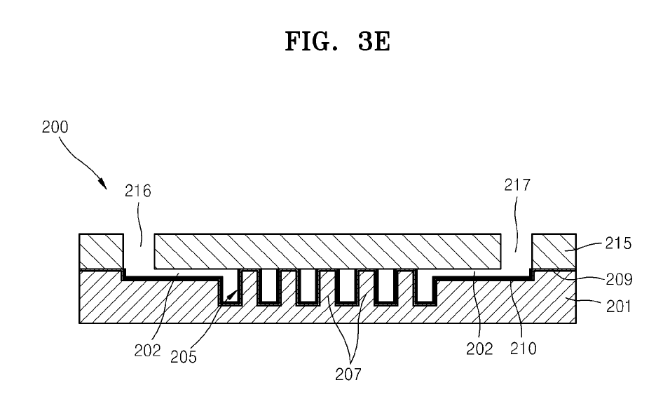

FIGS. 3A through 3E are cross-sectional views sequentially illustrating a method of fabricating a microfluidic chip according to another embodiment of the present invention. The fabrication method shown in FIGS. 3A through 3E may include a first process of preparing a lower substrate 201 on which a channel 202 and a chamber 205 are formed, a second process of forming an upper substrate 215 formed of Si, a third process of forming an organic thin film 210 on an upper surface of the lower substrate 201, a fourth process of removing the organic thin film 210 formed on an attaching area 212 of the upper surface of the lower substrate 201, and a fifth process of attaching the upper substrate 215 and the lower substrate 201 to each other. The first and third processes are shown in FIG. 3A, the fourth process is shown in FIGS. 3B and 3C, and the second process and the fifth process are shown in FIGS. 3D and 3E.

The first process and the third process are the same as the first and third processes for fabricating the microfluidic chip 100 described with reference to FIGS. 2A and 2B, and detailed descriptions for the above processes are omitted. Reference numeral 207 of FIG. 3A denotes a pillar, and reference numeral 209 denotes an oxide layer including SiO₂. The second process is the same as the second process for fabricating the microfluidic chip 100 described with reference to FIG. 2F, and detailed descriptions of the above process are omitted. Reference numeral 216 of FIG. 3D denotes an inlet hole, and reference numeral 217 denotes an outlet hole.

The fourth process includes placing a flat photocatalyst plate 20 on the lower substrate 201 and irradiating UV rays onto the photocatalyst plate 20 (refer to FIG. 3B), and washing the lower substrate 201 to remove the organic thin film 210 from the attaching area 212 (refer to FIG. 3C). Referring to FIG. 3B, the photocatalyst plate 20 includes a photocatalyst material. The photocatalyst material causes a reaction of decomposing the organic thin film 210 when it is exposed to UV rays when contacting the organic thin film 210, for example, can be TiO₂, ZnO, SnO₂, SrTiO₃, WO₃, B2O₃, or Fe₂O₃. Portions of the lower substrate 201, which contact the photocatalyst plate 20, coincide with the attaching area 212 (refer to FIG. 3C).

When the UV rays are irradiated onto the photocatalyst plate 20, the photocatalyst plate 20 is exposed, and at the same time, some parts of the organic thin film 210 contacting the photocatalyst plate 20 are decomposed by the photocatalyst material. Referring to FIG. 3C, when the photocatalyst plate 20 is separated from the lower substrate 201 after irradiating the UV rays, the attaching area 212 formed by removing the organic thin film 210 from the lower substrate 201 due to the decomposition operation of the photocatalyst material is exposed.

On the other hand, according to the method of removing the organic thin film 210 shown in FIGS. 3B and 3C, since the decomposition of the organic thin film 210 is diffused on a peripheral portion of the contact area between the photocatalyst plate 20 and the organic thin film 210, an error of the attaching area 212 may be larger than an error of the attaching area 112 that is formed by the method of removing the organic thin film 110 shown in FIGS. 2C through 2E. Therefore, if a highly accurate microfluidic chip has to be fabricated, the microfluidic chip may be fabricated using the method shown in FIGS. 2A through 2G.

The fifth process includes activating a lower surface of the upper substrate 215 by performing an O₂-plasma process, in order to collide O₂-plasma with the lower surface of the upper substrate 215, as shown in FIG. 3D, and attaching the lower surface of the upper substrate 215 onto the upper surface of the lower substrate 201 to form the microfluidic chip 200 as shown in FIG. 3E.

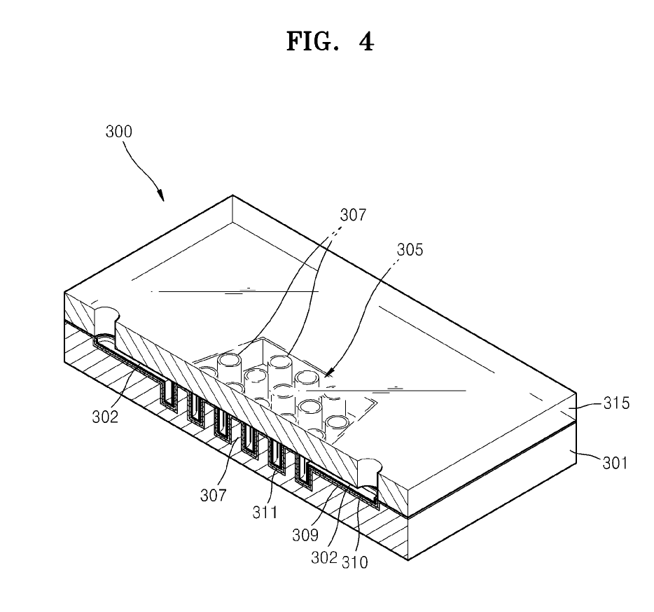

FIG. 4 is a partially cut perspective view showing a microfluidic chip 300 according to another embodiment.

Referring to FIG. 4, the microfluidic chip 300 of the current embodiment also includes a lower substrate 301 and an upper substrate 315, which are attached to each other. The lower substrate 301 is formed of Si, and includes a channel 302, a chamber 305, and a plurality of pillars 307 on an upper surface thereof. The pillars 307 are arranged to be separated from each other in the chamber 305, and protrude from the upper surface of the lower substrate 301 so that they contact the lower surface of the upper substrate 315.

The surface of the lower substrate 301 formed of Si is oxidized by the oxygen in the air, and thus, an oxide layer 309 including SiO₂ is formed. On the other hand, if the lower substrate 301 is formed of a polymer such as PDMS (polydimethylsiloxane), PMMA (polymethylmetaacrylate), PC (polycarbonate), and PE (polyethylene), an oxide layer including SiO₂ or TiO₂ or a nitride layer including SiN can be specifically formed.

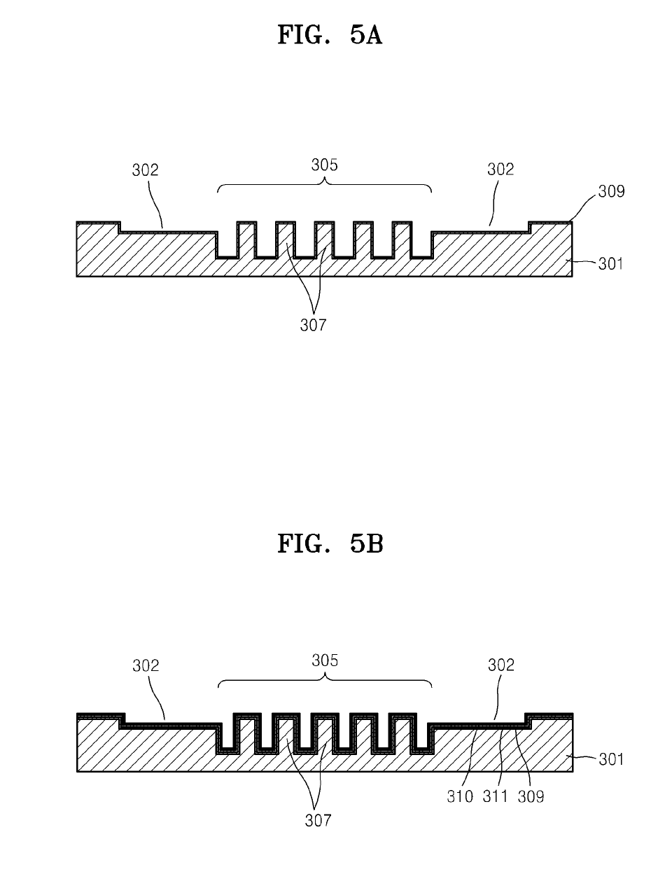

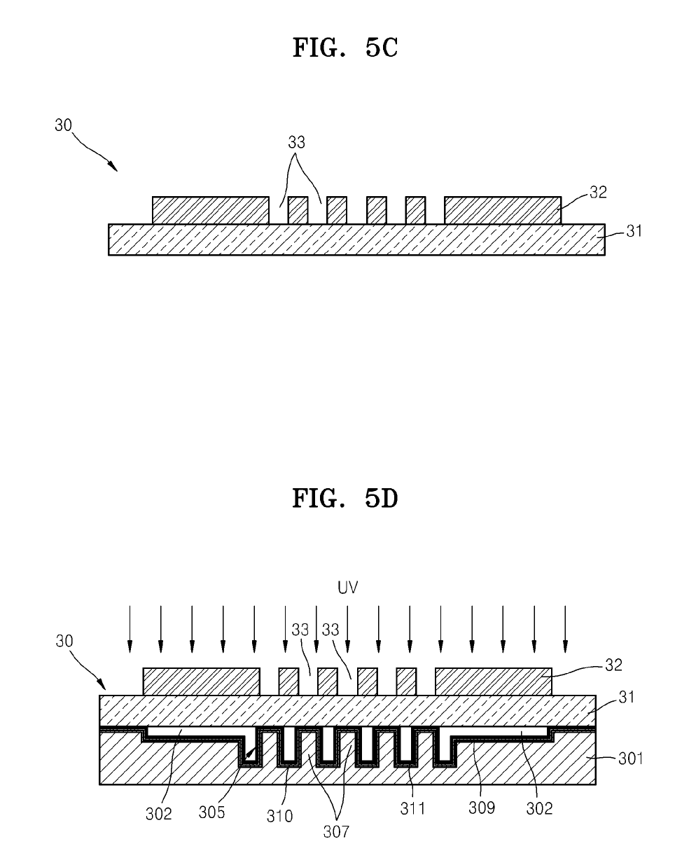

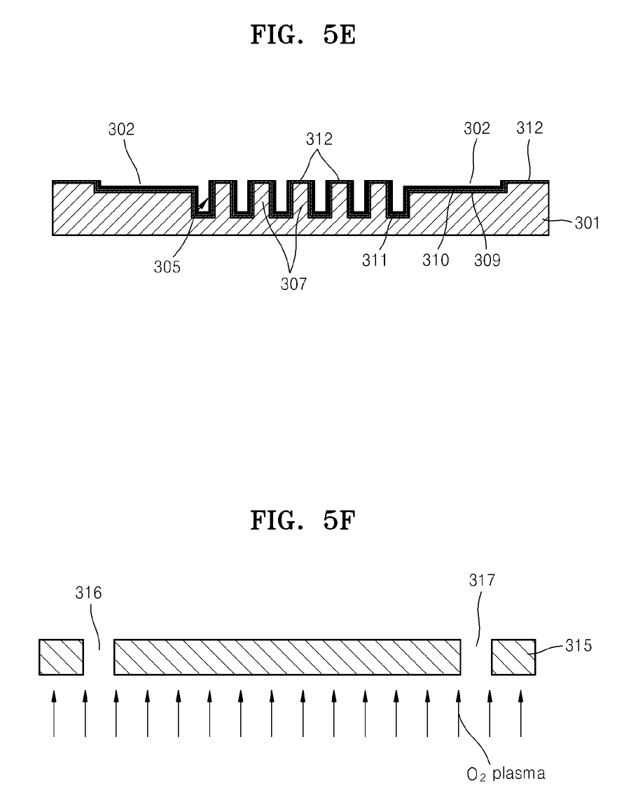

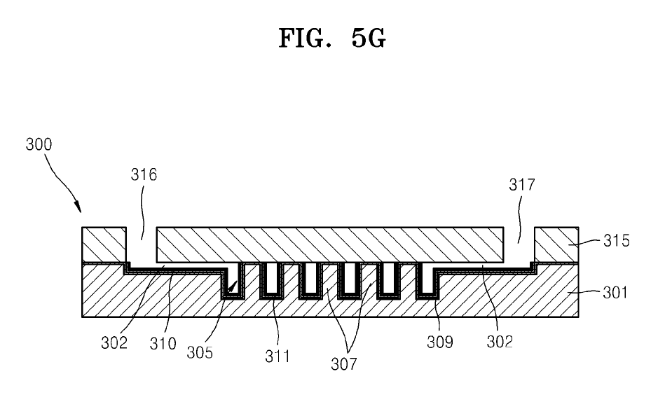

A photocatalyst layer 311 including a photocatalyst material is deposited on the oxide layer 309. The photocatalyst material can be TiO₂, ZnO, SnO₂, SrTiO₃, WO₃, B₂O₃, or Fe₂O₃. An organic thin film 310 is formed on the photocatalyst layer 311. The organic thin film 310 is the same as the organic thin film 110 included in the microfluidic chip 100 of FIG. 1, and detailed descriptions for the organic thin film 310 are omitted. The organic thin film formed on an attaching area 312 (refer to FIG. 5E) on the upper surface of the lower substrate 301 is removed.

The upper substrate 315 is formed of PDMS (polydimethylsiloxane) that is a silicon resin. The upper substrate 315 includes an inlet hole 316 and an outlet hole 317.

FIGS. 5A through 5G are cross-sectional views illustrating a method of fabricating the microfluidic chip shown in FIG. 4. The method of fabricating the microfluidic chip 300 includes a first process of preparing the lower substrate 301 including the channel 302 and the chamber 305, a second process of preparing the upper substrate 315 formed of Si, a third process of forming the organic thin film 310 on the upper surface of the lower substrate 301, a fourth process of removing the organic thin film 310 formed on the attaching area 312 of the lower substrate 301, and a fifth process of attaching the upper substrate 315 and the lower substrate 301 to each other. In addition, the method of the current embodiment can further include a process of forming a photocatalyst layer 311 on the upper surface of the lower substrate 301 before the third process.

Referring to FIG. 5A, the first process includes preparing the lower substrate 301 formed of Si, and forming the channel 302, the chamber 305, and the plurality of pillars 307 on the upper surface of the lower substrate 301. The first process is the same as the first process for fabricating the microfluidic chip 100 described with reference to FIG. 2A, and thus, detailed descriptions for the first process are omitted here. In the second process, a mixed solution of the PDMS resin and the linking agent is injected into a mold (not shown) corresponding to the shape of the upper substrate 315, and is cured and separated from the mold to form the upper substrate 315 (refer to FIG. 5F) including the PDMS. In addition, the inlet hole 316 and the outlet hole 317 can be formed in the upper substrate 315. The second process is also the same as the second process for fabricating the microfluidic chip 100 described with reference to FIG. 2F, and thus, detailed descriptions for the second process are omitted.

Referring to FIG. 5B, the photocatalyst layer 311 including the photocatalyst material is formed on the upper surface of the lower substrate 315. The photocatalyst layer 311 can be formed by spin-coating a solution including the photocatalyst material onto the lower substrate 301, and then, baking the coated solution. Otherwise, the photocatalyst layer 311 can be formed using the CVD method or the PVD method. In the third process, the organic thin film 310 is formed on the photocatalyst layer 311. The process of forming the organic thin film 310 is the same as the third process for fabricating the microfluidic chip 100 described with reference to FIG. 2B, and thus, detailed descriptions for the process are omitted.

The fourth process includes forming a photo mask 30 (refer to FIG. 5C), arranging the photo mask 30 on the upper surface of the lower substrate and irradiating the UV rays onto the photo mask 30 (refer to FIG. 5D), and washing the lower substrate 301 to remove the organic thin film 310 from the attaching area 312 (refer to FIG. 5E).

Referring to FIG. 5C, the photo mask 30 includes a flat transparent plate 31 and a photoresist layer 32 formed on the transparent plate 31. The photoresist layer 32 includes a pattern 33 corresponding to portions of the lower substrate 301 from which the organic thin film 310 will be removed, that is, corresponding to the attaching area 312 (refer to FIG. 5E). A method of forming the photoresist is the same as the method described with reference to FIG. 2C, and detailed descriptions for that are omitted.

Referring to FIG. 5D, the photo mask 30 is arranged on the upper surface of the lower substrate 301 so that the pattern 33 of the photoresist layer 32 can overlap with the attaching area 312 (refer to FIG. 5F), and the UV ray is irradiated on the photo mask 30. When the UV rays are irradiated onto the photo mask 30, the organic thin film 310 and the photocatalyst layer 309 under the organic thin film 310 are partially exposed to the UV ray through the pattern 33. Therefore, some parts of the organic thin film 310, which contact the photocatalyst layer 309 and are exposed to the UV ray, are decomposed by the photocatalyst material.

Referring to FIG. 5E, when the photo mask 30 is separated from the lower substrate 301 after irradiating the UV rays to the photo mask 30, the attaching area 312 that is formed by removing the organic thin film 310 from the lower substrate 301 due to the decomposition of the photocatalyst material is exposed. In the fifth process, an O₂-plasma process, by which O₂-plasma is collided with the lower surface of the upper substrate 315 formed in the second process, is performed to activate the lower surface of the upper substrate 315 as shown in FIG. 5F, and then, the lower surface of the upper substrate 315 is adhered to the upper surface of the lower substrate 301 to be attached to the lower substrate. Thus, the microfluidic chip 300 is formed as shown in FIG. 5G.

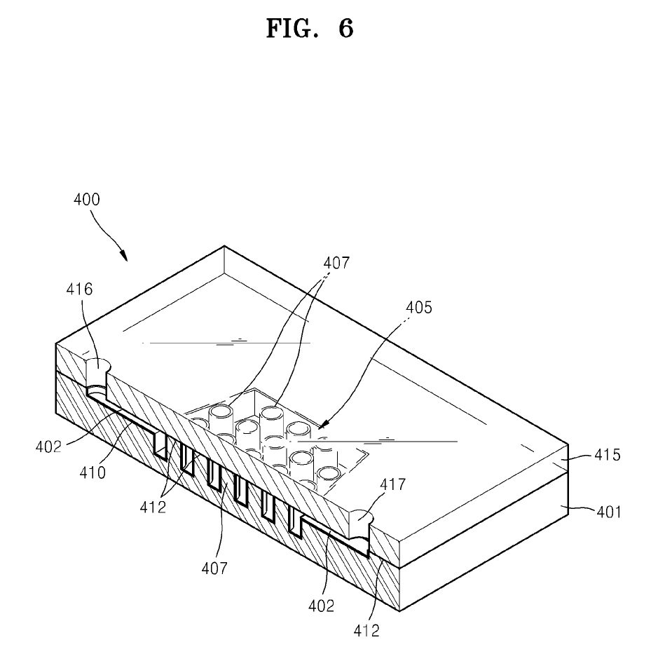

FIG. 6 is a partially cut perspective view showing a microfluidic chip according to another embodiment.

Referring to FIG. 6, the microfluidic chip 400 according to the current embodiment also includes a lower substrate 401 and an upper substrate 415, which are attached to each other. The lower substrate 401 includes a photocatalyst material, and the photocatalyst material may be TiO₂. A channel 402, a chamber 405, and a plurality of pillars 407 are formed on an upper surface of the lower substrate 401. As described with reference to FIG. 2A, the channel 402, the chamber 405, and the pillars 407 can be formed using an etching process or a machining process.

Since TiO₂ is an oxide material that can help the attachment between the upper substrate 415 and the lower substrate 401, the lower substrate 401 does not require an additional oxide layer like the oxide layer 109 shown in FIG. 1. An organic thin film 410 is formed on the upper surface of the lower substrate 401. The organic thin film 410 can be formed using the same process for forming the organic thin film 110 described with reference to FIG. 2B, and thus, detailed descriptions for the process of forming the organic thin film 410 are omitted. The organic thin film 410 formed on an attaching area 415 of the upper surface of the lower substrate, which is attached to the upper substrate 415, is removed. The method of removing the organic thin film 410 is the same as the method described with reference to FIGS. 5C through 5E, that is, a photo mask including a flat transparent plate and a photoresist layer formed on the transparent plate is arranged on the lower substrate 401 and the UV ray is irradiated to the photo mask to partially decompose the organic thin film.

The upper substrate 415 is formed of a silicon resin, for example, PDMS (polydimethylsiloxane), and includes an inlet hole 416 and an outlet hole 417. As described with reference to FIGS. 5F and 5G, the lower surface of the upper substrate 415 is activated to be easily attached by performing the O₂-plasma process, and then, the lower surface of the upper substrate 415 is adhered to the upper surface of the lower substrate 401 to attach the upper and lower substrates 415 and 401 to each other. Then, the microfluidic chip 400 is formed.

On the other hand, cell capture experiments and polymerase chain reaction (PCR) experiments were performed using the microfluidic chip 100 of the present invention and the conventional microfluidic chip having the lower substrate formed of Si and the upper substrate formed of a glass material, and the results of the experiments were compared. Since equivalent results were obtained within an acceptable error range, and thus, it could be determined that the microfluidic chip 100 can be used instead of the conventional microfluidic chip in microfluidics.

The microfluidic chip, in which the organic thin film is formed on the inner surfaces of the chamber, can be fabricated using silicon resin that can be easily formed and is cheaper than the glass material. Therefore, the costs for fabricating the microfluidic chip can be reduced, and a defect rate can be reduced and a production yield can be improved by generating the organic thin film before the bonding process.

According to another embodiment, a microfluidic structure includes a first substrate, a second substrate, and a polysiloxane layer disposed between the first and second substrates, wherein the polysiloxane layer is coupled to the first and second substrates via a SiO₂ layer.

The SiO₂ layer may be deposited on the first and second substrates. The first and second substrates may be formed of a solid support, for example, a material selected from the group consisting of plastic, silicon, and glass. The plastic may have a hydrophilic or a hydrophobic surface, for example, may be one of selected from the group consisting of polyethylene, polypropylene, polystyrene, polyurethane, polysulfone, PTFE, PVC, polycarbonate, and PMMA, however, the embodiments of the present invention are not limited thereto.

One or more of the first and second substrates may include a micro-structure. The micro-structure may not be in micro-meter level, but may have a small structure. For example, at least one cross-section of the micro-structure, that is, a diameter, an width, and a height of the micro-structure may be in ranges of about 10 nm to about 1000 mm, from about 10 nm to about 100 mm, or from about 10 nm to about 10 mm. The micro-structure may provide the fluid with a path. For example, the micro-structure may be selected from the group consisting of a channel, a chamber, an inlet, and an outlet. A part of the micro-structure may be formed on the surface or inner space of the substrate, or on the surface and in the inner space of the substrate.

The microfluidic structure includes a polysiloxane layer disposed between the first substrate and the second substrate, and the polysiloxane layer is coupled to the first and second substrates via the SiO₂ layer.

The polysiloxane may be one of PDMS and diphenylsiloxane.

The polysiloxane layer may be formed as a film. The film may have a thickness of about 10 to about 500 μm, or about 100 to about 300 μm.

The polysiloxane layer may be coupled to entire surfaces of the first and second substrates. The polysiloxane layer may be simple membrane without including the micro-structure. Otherwise, the polysiloxane layer may be coupled to a part of the surfaces of the first and second substrates.

The SiO₂ layer is strongly adhered to the polysiloxane. Therefore, the SiO₂ layer may be deposited onto the first and second substrates and fixed on the substrates, and then, may be adhered to the polysiloxane layer. The deposition of SiO₂ layer onto the first and second substrates may be performed using a method selected from the group consisting of the liquid phase deposition, evaporation, and sputtering method.

The microfluidic structure is a device including one or more micro-structures. The micro-structure is described above. The microfluidic structure may be a microfluidic apparatus, an inlet and an outlet of which are connected to each other through one or more channels. The microfluidic apparatus may further include an additional structure of a valve, a pump, or a chamber.

The microfluidic structure includes the first substrate having a surface on which a pneumatic channel is formed, and the second substrate having a surface on which a fluid channel is formed. In addition, the polysiloxane layer is disposed between the above surfaces of the first and second substrates so that the polysiloxane layer is deflected to control the flow of the fluid in the fluid channel when a pressure or vacuum is applied to the pneumatic channel. The polysiloxane layer generally blocks the flow of the fluid in the fluid channel, and when a pressure or vacuum is applied to the pneumatic channel, the polysiloxane layer may be deflected to flow the fluid in the fluid channel. The microfluidic structure may further include an additional surface and a layer. The additional surface may be an additional channel for providing the fluid with a flow path. The second substrate may include a plurality of bias channels for providing the fluid with flow paths. The microfluidic structure may include a plurality of valves realized by the polysiloxane layer, which are disposed as parts of the pumps.

The microfluidic structure may include the first substrate having a surface on which a pneumatic channel is formed, and the second substrate having a surface on which a fluid channel is formed. In addition, the polysiloxane layer is disposed between the above surfaces of the first and second substrates so that the polysiloxane layer is deflected to activate a plurality of valves which may be switched pneumatically when a pressure or vacuum is applied to the pneumatic channel. In addition, the valves which may be pneumatically switched may control the flow of the fluid in the microfluidic apparatus. Here, the first substrate may include a plurality of etched channels, and the etched channels may distribute the pressure applied to the polysiloxane layer. In the microfluidic structure, three successive valves which may be pneumatically switched may form a pump. The three valves may include an input valve, a diaphragm valve, and an output valve.

According to another embodiment of the present invention, a method of fabricating a microfluidic structure includes providing a first substrate and a second substrate, on which micro-structures are formed, depositing a SiO₂ layer on surfaces of the first and second substrates, and coupling the first substrate and the second substrate by interposing polysiloxane between the surfaces of the first and second substrates on which SiO₂ layer is deposited.

The above method includes an operation of providing the first and second substrates on which micro-structures are formed. The micro-structures on the first and second substrates may be formed of a well-known method, for example, an injection molding, a photolithography, or a LIGA method.

The substrates may be formed of a solid support, for example, one selected from the group consisting of plastic, silicon, and glass. The plastic may include a hydrophilic surface or a hydrophobic surface, for example, may be one of selected from the group consisting of polyethylene, polypropylene, polystyrene, polyurethane, polysulfone, PTFE, PVC, polycarbonate, and PMMA.

The micro-structure may not be in micro-meter level, but may have a small structure. For example, at least one cross-section of the micro-structure, that is, a diameter, an width, and a height of the micro-structure may be in ranges of about 10 nm to about 1000 mm, from about 10 nm to about 100 mm, or from about 10 nm to about 10 mm. The micro-structure may provide the fluid with a path. For example, the micro-structure may be selected from the group consisting of a channel, a chamber, an inlet, and an outlet. A part of the micro-structure may be formed on the surface or inner space of the substrate, or on the surface and in the inner space of the substrate.

The above method also includes an operation of depositing SiO₂ on the surfaces of the first and second substrates. The depositing process may be performed by the method selected from the group consisting of the liquid phase deposition (LPD), evaporation method, sputtering method, and chemical vapor deposition (CVD) method. The LPD method includes an operation of forming hydrofluosilicic acid aqueous solution which is saturated at a room temperature by dissolving silicon dioxide powder in an aqueous solution including 34% of hydrofluosilicic acid (H₂SiF₆). The silicon dioxide powder which is not dissolved in the solution may be removed from the aqueous solution of hydrofluosilicic acid by using a filter paper. The saturated hydrofluosilicic acid solution may be changed into a supersaturated solution by adding water, boric acid aqueous solution, or ammonium hydroxide in the saturated aqueous solution. In addition, the substrates are dipped into the supersaturated solution to grow a silicon dioxide film on the surfaces of the substrates. The deposition may be performed in a temperature range of about 10° C. to about 50° C. The above deposition is a method of depositing the silicon dioxide film on the plastic substrates in a previously evacuated chamber by a glow discharge, and includes forming an air flow on outer portion of the chamber by evaporating organic silicon component and mixing the evaporated organic silicon component with an oxidizing agent and an inert gas; flowing the air flow to the chamber to be adjustable; establishing glow discharge plasma in the chamber from the air flow; flowing the air flow in the plasma to be adjustable while locking a part of the plasma therein; depositing a first coating of silicon dioxide on the substrates; removing and/or redistributing external surface particles from the substrates; and repeatedly performing the above operations to deposit a second coating of silicon dioxide on the substrates. The oxidizing agent may be oxygen. The organic silicon may be selected from the group consisting of 1,1,3,3-tetramethyldisiloxane, hexamethyldisiloxane, vinyltrimethylsilane, methyltrimethoxysilane, vinyltrimethoxysilane, and hexamethyldisilazane. However, the above method of depositing SiO₂ layer is an example, and other well known deposition methods may be used in one or more embodiments of the present invention. The operation of depositing SiO₂ layer may be performed before providing the substrates. That is, before forming the micro-structures on the substrates, the SiO₂ layer may be deposited, and then, the micro-structures may be formed.

The above method also includes an operation of coupling the first and second substrates to each other by interposing the polysiloxane between the surfaces, on which the SiO₂ layer is deposited, of the first and second substrates.

The operation of coupling the first and second substrates may include arranging the surface of the first substrate, the polysiloxane layer, and the surface of the second substrate to correspond to each other, and coupling them by compressing the first and second substrates.

The polysiloxane may be selected from the group consisting of PDMS and diphenylsiloxane.

The polysiloxane layer may be formed as a film. For example, the polysiloxane layer may have a thickness of about 10 μm to about 500 μm, or about 100 μl in to about 300 μm.

The polysiloxane layer may be coupled to entire surfaces of the first and second substrates. That is, the polysiloxane layer may not include the micro-structure. Otherwise, the polysiloxane layer may be coupled to a part of the surfaces of the first and second substrates.

The microfluidic structure is a device including one or more micro-structures. The micro-structure is described above. The microfluidic structure may be a microfluidic apparatus, an inlet and an outlet of which are connected to each other through one or more channels. The microfluidic apparatus may further include an additional structure of a valve, a pump, or a chamber.

The microfluidic structure includes the first substrate having a surface on which a pneumatic channel is formed, and the second substrate having a surface on which a fluid channel is formed. In addition, the polysiloxane layer is disposed between the above surfaces of the first and second substrates so that the polysiloxane layer is deflected to control the flow of the fluid in the fluid channel when a pressure or vacuum is applied to the pneumatic channel. The polysiloxane layer generally blocks the flow of the fluid in the fluid channel, and when a pressure or vacuum is applied to the pneumatic channel, the polysiloxane layer may be deflected to flow the fluid in the fluid channel. The microfluidic structure may further include an additional surface and a layer. The additional surface may be an additional channel for providing the fluid with a flow path. The second substrate may include a plurality of bias channels for providing the fluid with flow paths. The microfluidic structure may include a plurality of valves realized by the polysiloxane layer, which are disposed as parts of the pumps.

The microfluidic structure may include the first substrate having a surface on which a pneumatic channel is formed, and the second substrate having a surface on which a fluid channel is formed. In addition, the polysiloxane layer is disposed between the above surfaces of the first and second substrates so that the polysiloxane layer is deflected to activate a plurality of valves which may be switched pneumatically when a pressure or vacuum is applied to the pneumatic channel. In addition, the valves which may be pneumatically switched may control the flow of the fluid in the microfluidic apparatus. Here, the first substrate may include a plurality of etched channels, and the etched channels may distribute the pressure applied to the polysiloxane layer. In the microfluidic structure, three successive valves which may be pneumatically switched may form a pump. The three valves may include an input valve, a diaphragm valve, and an output valve.

Hereinafter, one or more embodiments will be described in more detail. However, one or more embodiments of the present invention are exemplary embodiments, and the scope of the invention is not limited thereto.

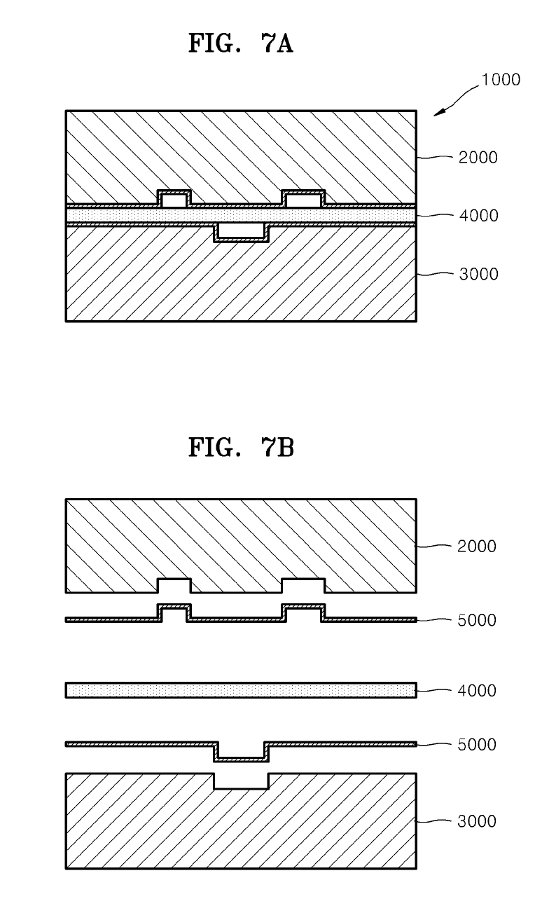

FIGS. 7A and 7B are diagrams showing an example of the microfluidic structure according to an embodiment. FIG. 7A is a side view of the microfluidic structure and FIG. 7B is an exploded view of the structure shown in FIG. 7A. Referring to FIGS. 7A and 7B, the microfluidic structure 1000 includes a first substrate 2000, a second substrate 3000, and a polysiloxane layer 4000 disposed between the first and second substrates 2000 and 3000. The polysiloxane layer 4000 is coupled to the first and second substrates 2000 and 3000 via a SiO₂ layer 5000. The first and second substrates 2000 and 3000 include micro-structures, for example, channels, on surfaces thereof. The SiO₂ layer 5000 is deposited on the surfaces of the first and second substrates 2000 and 3000. The first and second substrates 2000 and 3000 are coupled to each other while interposing the polysiloxane layer 4000 to form the microfluidic structure 1000. The polysiloxane layer 4000 may be formed of PDMS or diphenylsiloxane.

Referring to FIG. 7B, the SiO₂ layer 5000 is deposited on the micro-structure, that is, deposited after forming the micro-structure. However, the SiO₂ layer 5000 may be deposited before forming the micro-structures or during forming the micro-structures so that the SiO₂ layer 5000 may not be deposited on portions corresponding to the micro-structures.

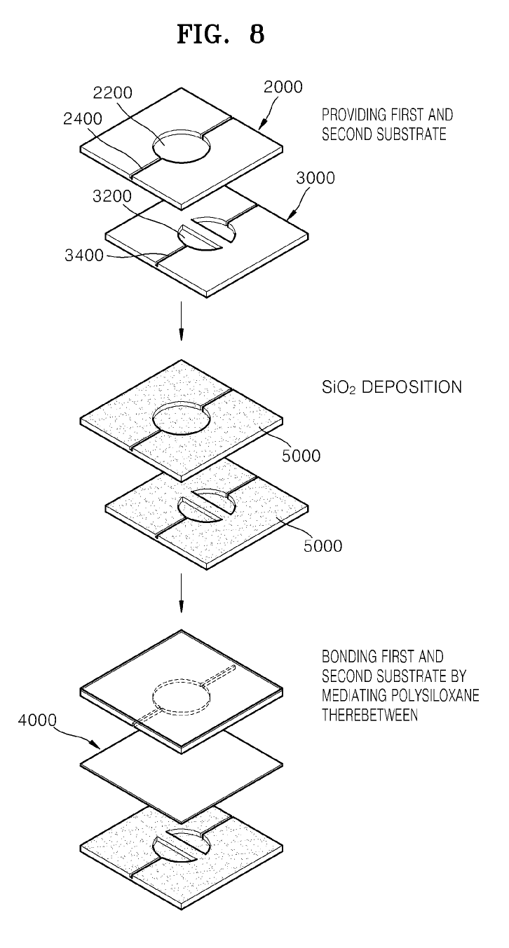

FIG. 8 is a diagram illustrating a method of fabricating the microfluidic structure according to an embodiment of the present invention.

Referring to FIG. 8, the first and second substrates 2000 and 3000 are provided. The micro-structures may be formed on the first and second substrates 2000 and 3000, and the micro-structures may be fabricated by the injection molding method or the photolithography method. The first and second substrates 2000 and 3000 are formed of plastic, and the micro-structures may be fabricated by the injection molding. In addition, the SiO₂ layer 5000 is deposited on the surfaces, on which the micro-structures are formed, of the first and second substrates 2000 and 3000. The deposition may be performed by the liquid phase deposition, the evaporation, and the sputtering. Next, the polysiloxane layer 4000 is arranged between the surfaces on which the SiO₂ layer 5000 is deposited, and then, the first and second substrates 2000 and 3000 are compressed to be coupled to each other so as to fabricate the microfluidic structure.

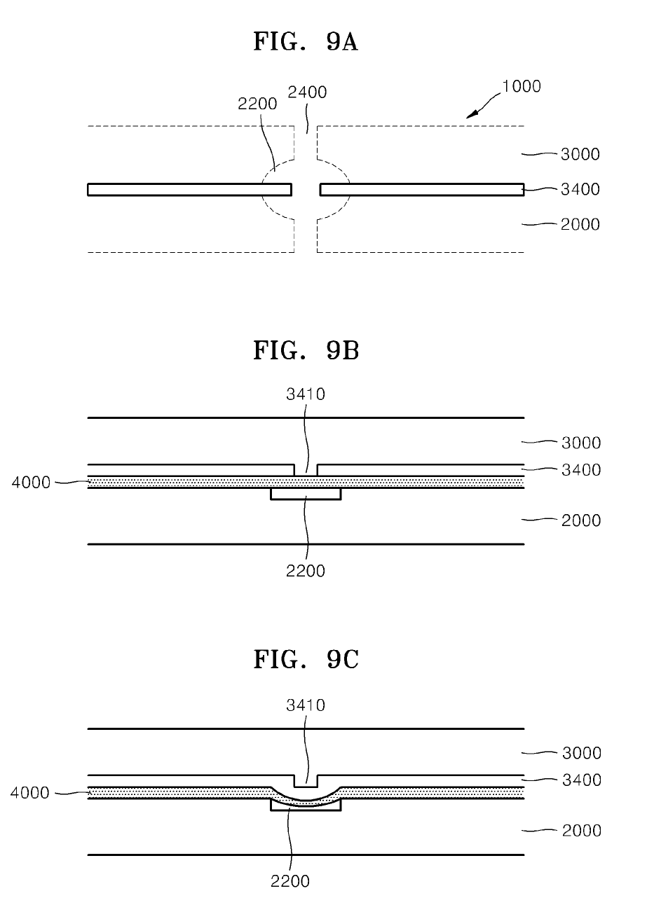

In the microfluidic structure fabricated by the method illustrated in FIG. 8, the micro-structures may be a pneumatic channel 2400 and a pneumatic valve 2200 formed on the first substrate 2000, and a fluid channel 3400 and a fluid valve 3200 formed on the second substrate 3000. The first and second substrates 2000 and 3000 are arranged and coupled to each other in a way to render the pneumatic valve 2200, the polysiloxane layer 4000, and the fluid valve 3200 may perform as a diaphragm valve or a pump. The micro-structures performing as the pump or the valve will be described with reference to FIG. 9.

FIGS. 9A through 9C are diagrams of a microfluidic structure according to another embodiment. FIGS. 9A through 9C show a film valve which may be installed in the microfluidic structure. FIG. 9A is a plan view of the film valve, and FIGS. 9B and 9C are side views showing the film valve in a closed state and in an open state. The microfluidic structure includes the polysiloxane layer disposed between two plastic substrates 2000 and 3000. The polysiloxane layer may be HT-6135 or HT-6240 having a thickness of about 254 μm manufactured by Bisco, Inc. The polysiloxane layer is strongly coupled to the surfaces of the two substrate on which SiO₂ layer is deposited. The fluid channel 3400 is used to convey the fluid. The pneumatic channel 2400 and the valve region 2200 are etched to convey air or other fluids in order to activate the valve under a pressure or a vacuum status. In general, the pneumatic channels 2400 and 2200 are located in a substrate 2000 (referred to as pneumatic substrate), and the fluid channel 3400 is located in the other substrate 3000 (referred to as fluid substrate). The pneumatic substrate may include a port providing the pneumatic channel with a pressure or vacuum.

The valve illustrated in FIGS. 9A through 9C is operated as follows. Activated vacuum is provided to the valve region 2200 through a pneumatic channel 2400. The applied vacuum deflects the polysiloxane layer 4000 at the portion which locates at or around the valve region 2200, toward a portion which is apart from the discontinued point 3410 of the fluid channel to provide a path through which the fluid may flow. Therefore, the valve is opened as shown in FIG. 9C. The surface of the discontinued point (3410) may not contain SiO₂ layer so that the polysiloxane layer 4000 may contact with the surface of the discontinued point (3410) to block the flow of fluid in the fluid channel when a pressure or a vacuum pressure is not applied to the pneumatic channel, and to be deflected to control a flow of the fluid in the fluid channel when a pressure or a vacuum pressure is applied to the pneumatic channel. The valve which may be opened and closed by using the pneumatic pressure is referred to as a switchable valve or a pneumatically switchable valve. When the pressure or the vacuum is not applied to the polysiloxane layer 4000, the polysiloxane layer 4000 blocks the fluid channel as shown in FIG. 9B.

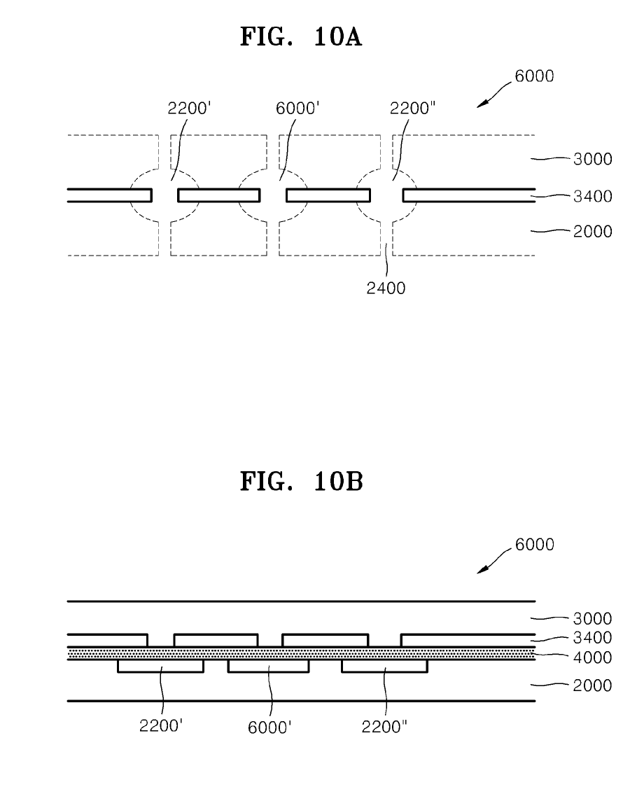

The film valve may form various modes of controlling the fluid. FIGS. 10A and 10B are diagrams of a pump formed by using the film valve. FIGS. 10A and 10B are a plan view and a side view of a film pump. Referring to FIGS. 10A and 10B, three successive film valves form a diaphragm pump 6000. Pumping operation is performed by activating the valves according to five-periods. The diaphragm pump 6000 includes an input valve 2000, a diaphragm valve 6000′, and an output valve 2200″. Since the diaphragm pump 6000 may operate in any direction, the input valve 2200′ and the output valve 2200″ may be changed with each other. The diaphragm pump 6000 includes the fluid substrate 3000 including the etched fluid channel 3400, the polysiloxane layer 4000, and the pneumatic substrate 2000. The polysiloxane layer 4000 is coupled to the fluid substrate 3000 and the pneumatic substrate 2000 via the SiO₂ layer. The pumping operation may be performed in series of processes. The output valve 2200″ is closed, and the input valve 2200′ is opened. Then, the diaphragm valve 6000′ is opened. In addition, the input valve 2200′ is closed. After that, the output valve 2200″ is opened. Also, the diaphragm valve 6000′ is closed, and the fluid is pumped through the opened output valve 2200″. The valve may perform as a pump, a mixer, or a router.

According to the microfluidic structure of one or more embodiments, the microfluidic structure may be fabricated in a simple way. Therefore, the microfluidic structure including various micro-structures on the substrates of various materials may be fabricated efficiently.

According to the method of fabricating the microfluidic structure of one or more embodiments, the microfluidic structure may be fabricated effectively and easily.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A microfluidic structure comprising:
a first substrate;
a second substrate; and
a polysiloxane layer disposed between the first and second substrates,
wherein the polysiloxane layer is coupled to the first and second substrates via an SiO₂ layer.

2. The microfluidic structure of claim 1, wherein the first and second substrates are formed of a material selected from the group consisting of plastic, silicon, glass, and mixtures thereof.

3. The microfluidic structure of claim 2, wherein the plastic may be selected from the group consisting of polyethylene, polypropylene, polystyrene, polyurethane, polysulfone, polytetrafluoroethylene (PTFE), polyvinylchloride (PVC), polycarbonate, polymethacrylate (PMMA), and mixtures thereof.

4. The microfluidic structure of claim 1, wherein the polysiloxane is polydimethysiloxane (PDMS).

5. The microfluidic structure of claim 1, wherein the first and second substrates include channels.

6. The microfluidic structure of claim 1, wherein the first substrate includes a surface on which a pneumatic channel is formed, the second substrate includes a surface on which a fluid channel is formed, and the polysiloxane layer is disposed between the surfaces of the first and second substrates to be deflected to control a flow of the fluid in the fluid channel when a pressure or a vacuum pressure is applied to the pneumatic channel.

7. The microfluidic structure of claim 6, wherein the polysiloxane layer blocks the flow of fluid in the fluid channel, and when the pressure or vacuum is applied to the pneumatic channel, the polysiloxane layer is deflected to make the fluid flow in the fluid channel.

8. The microfluidic structure of claim 1, wherein the polysiloxane layer is coupled to a part or entire surfaces of the first and second substrates.

9. The microfluidic structure of claim 1, wherein the polysiloxane layer is formed as a film.

10. A method of fabricating a microfluidic structure, the method comprising:
providing a first substrate and a second substrate on which micro-structures are formed;
depositing an SiO₂ layer on surfaces of the first and second substrates; and
coupling the first and second substrates to each other by interposing a polysiloxane layer between the surfaces, on which the SiO₂ layer is deposited, of the first and second substrates.

11. The method of claim 10, wherein the first substrate and the second substrate include micro-structures formed by an injection molding method, a photolithography method, or a Lithographie, Galvanoformung, and Abformung (LIGA) method.

12. The method of claim 10, wherein the depositing of SiO₂ is performed by a method selected from the group consisting of a liquid phase deposition method, an evaporation method, a sputtering method, and mixtures thereof.

13. The method of claim 10, wherein the coupling of the first and second substrates is performed by arranging the surface of the first substrate, the polysiloxane layer, and the surface of the second substrate, and compressing the first and second substrates.

14. The method of claim 10, wherein the first and second substrates are formed of a material selected from the group consisting of plastic, silicon, glass, and mixtures thereof.

15. The method of claim 14, wherein the plastic may be selected from the group consisting of polyethylene, polypropylene, polystyrene, polyurethane, polysulfone, polytetrafluoroethylene (PTFE), polyvinylchloride (PVC), polycarbonate, polymethacrylate (PMMA), and mixtures thereof.

16. The method of claim 10, wherein the polysiloxane is polydimethysiloxane (PDMS).

17. The method of claim 10, wherein the micro-structures of the first and second substrates include channels.

18. The method of claim 10, wherein the first substrate includes a surface on which a pneumatic channel is formed, the second substrate includes a surface on which a fluid channel is formed, and the microfluidic structure includes the polysiloxane layer disposed between the surfaces of the first and second substrates to be deflected to control a flow of the fluid in the fluid channel when a pressure or a vacuum pressure is applied to the pneumatic channel.

19. The method of claim 18, wherein the polysiloxane layer blocks the flow of fluid in the fluid channel, and when the pressure or vacuum is applied to the pneumatic channel, the polysiloxane layer is deflected to make the fluid flow in the fluid channel.

20. The method of claim 10, wherein in the coupling of the first and second substrates, the polysiloxane layer is coupled to a part or entire surfaces of the first and second substrates.

21. The method of claim 10, wherein the polysiloxane layer is formed as a film.
